(19) United States
(12) Patent Application Publication
(10) Pub. No.: US 2006/0267220 A1
(43) Pub. Date: Nov. 30, 2006

(54) Semiconductor device

(76) Inventors: Satoru Konishi, Saku (JP); Tsuneo Endoh, Komoro (JP); Hirokazu Nakajima, Saku (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/499,760

(22) Filed: Aug. 7, 2006

Related U.S. Application Data
(63) Continuation of application No. 10/808,389, filed on Mar. 25, 2004.

(30) Foreign Application Priority Data
Mar. 26, 2003 (JP) 2003-086158

(51) Int. Cl. H01L 23/52

(52) U.S. Cl. 257/784

(57) ABSTRACT

A semiconductor device comprises a module board having a top surface and a backside surface, a lower chip having a first circuit operated by a first frequency and a second circuit operated by a second frequency, an upper chip disposed so as to overlie over the lower chip, having the first circuit and the second circuit, a plurality of wires electrically bonding the upper chip to the module board, and electrically bonding the lower chip to the module board, respectively, and a plurality of chip components on the module board, and the first circuit of the upper chip is disposed opposite to the second circuits of the lower chip while the second circuit of the upper chip is disposed opposite to the first circuits of the lower chip. As a result, interference by high frequencies is rendered hard to occur between the wires bonded to the upper and lower chips, respectively, at a time when those circuits having respective frequencies are in operation, thereby enabling reliability of the semiconductor device to be enhanced.

This application is a Continuation application of U.S. application Ser. No. 10/808,389, filed Mar. 25, 2004, the entire disclosure of which is hereby incorporated by reference.

### CROSS-REFERENCE TO RELATED APPLICATION

The present application claims priority from Japanese Patent application JP 2003-086158, filed on Mar. 26, 2003, the content of which is hereby incorporated by reference into this application.

### BACKGROUND OF THE INVENTION

The present invention relates to a semiconductor device, and in, more particularly, to a technique which is effective for application to a module, such as a power amp module, and so forth, in order to enhance a reliability thereof.

As a structure for achieving a reduction in the size of a semiconductor device, there is a known SCP (Stacked Chips Package) structure in which semiconductor chips are disposed so as to be stacked one over the other. With the SCP structure, an upper layer chip that is smaller than a lower layer chip is stacked over the lower layer chip, so that the chips are configured in two stages, thus achieving a reduction in size (refer to, for example, Patent Document 1).

[Patent Document 1]

Japanese Unexamined Patent Publication No. Hei 7(1995)-58280 (page 2, FIG. 2).

### SUMMARY OF THE INVENTION

A multitude of electronic components are assembled in communication terminal equipment, such as a cellular phone, and there have been rapid advances toward a reduction in the size and a higher performance with respect to a high frequency amplifier (power amp module) that is assembled in a receiving system of the cellular phone, among communication terminal equipment. As one example of such communication systems, the GSM (Global System for Mobile communications) is well known.

At present, the power amp module for use in the GSM is 10 mm long and 8 mm wide in its outer dimensions, however, it is presumed that one that is 6 mm long and 5 mm wide will be available as the power amp module of the next generation.

Further, in the field of CDMA (Code Division Multiple Access) as well, it is presumed that the present power amp module that is 6 mm long and 6 mm wide in its outer dimensions will be subjected to sequential changes in outer dimensions to 5 mm long and 5 mm wide, and then, to 4 mm long and 4 mm wide.

In the case of such an ultra-small power amp module, with only a two-dimensional surface mounting of components on a module board of a printed wiring board (PWB), it becomes impossible to mount semiconductor chips that have active elements, such as transistors and so forth, and chip components comprising passive elements, such as resistors (chip resistors), capacitors (chip capacitors) and so forth, so that three-dimensional mounting is required.

Accordingly, from the viewpoint of achieving a reduction in the size of the power amp module, we have conducted intensive studies on a structure in which semiconductor chips are stacked one over the other, and, as a result, the following problems have been elicited.

In the case of adopting a structure in which semiconductor chips are stacked one over the other in a power amp module, there arises the problem that interference due to high frequencies occurs between wires bonded to an upper chip and a lower chip, respectively, thereby rendering the amplifier operation unstable.

For example, when the power amp module has amplifier circuits for two types of high frequencies, each amplifying an input signal in three stages, and the amplifier circuits for the second and third (final) stages, respectively, are installed in a lower chip where it is easy to reinforce GND, while the amplifier circuits for the initial stage are installed in an upper chip; and, because the amplifier circuits for the two types of frequencies are disposed on the same side of the upper and lower semiconductor chips, respectively, interference due to the high frequencies occurs between the wires bonded to the upper chip and the lower chip, respectively, at the time of an amp operation, thereby causing the amp operation to become unstable. Accordingly, there arises a problem of deterioration in the reliability of the power amp module.

It is therefore an object of the present invention to provide a semiconductor device in which the reliability thereof is enhanced.

Another object of the invention is to provide a semiconductor device in which a reduction in size can be achieved.

The above and other objects and novel features of the present invention will become apparent from the following description, taken in connection with the accompanying drawings.

An outline of a representative one among various embodiments of the present invention, as disclosed in the present application, will be briefly described as follows.

That is, a semiconductor device, according to the present invention, comprises a printed wiring board, having a top surface and a backside surface that is disposed on the side of the printed wiring board opposite from the top surface; a second semiconductor chip mounted over the top surface of the module board, having first circuits operated at a first frequency and second circuits operated at a second frequency; a first semiconductor chip, disposed so as to overlie the second semiconductor chip and having a first circuit and a second circuit; and a plurality of conductive wires electrically bonding the first semiconductor chip to the printed wiring board; wherein the first circuit of the first semiconductor chip is disposed opposite to the second circuits of the second semiconductor chip, while the second circuit of the first semiconductor chip is disposed opposite to the first circuits of the second semiconductor chip.

### BRIEF DESCRIPTION OF THE DRAWINGS

FIG. 1 is a sectional view showing the construction of a power amp module, which represents an example of Embodiment 1 of a semiconductor device according to the invention;

FIG. 2 is a backside plan view showing the construction of the power amp module shown in FIG. 1;

FIG. 3 is a plan view showing an example of the disposition of various mounted components provided on the top surface side of a printed wiring board of the power amp module in FIG. 1;

FIG. 4 is a circuit block diagram showing an example of the configuration of high frequency amplifiers installed in the power amp module shown in FIG. 1;

FIG. 5 is a plan view showing an example of a layout of amplifier circuits in a lower chip (second semiconductor chip) of the power amp module in FIG. 1;

FIG. 6 is a plan view showing an example of a layout of amplifier circuits in an upper chip (first semiconductor chip) of the power amp module in FIG. 1;

FIG. 7 is a plan view showing an example of a layout of amplifier circuits in a lower chip of a power amp module according to a variation of Embodiment 1 of the invention;

FIG. 8 is a plan view showing an example of a layout of amplifier circuits in an upper chip of the power amp module according to the variation of Embodiment 1 of the invention;

FIG. 9 is a plan view showing an example of a layout of amplifier circuits in a lower chip of Embodiment 2 of a power amp module according to the invention;

FIG. 10 is a plan view showing an example of a layout of amplifier circuits in an upper chip of Embodiment 2 of the power amp module according to the invention;

FIG. 11 is a plan view showing an example of a wiring state in upper and lower chips, respectively, of Embodiment 3 of a power amp module according to the invention; and

FIG. 12 is a sectional view showing the construction of a power amp module as an example of Embodiment 4 of a semiconductor device according to the invention.

### DETAILED DESCRIPTION OF THE PREFERRED EMBODIMENTS

Embodiments of the invention will be described in detail hereinafter with reference to the accompanying drawings.

The embodiments may be described by dividing them into a plurality of sections or by considering the embodiment as a whole as necessary for convenience's sake, however, it is to be understood that the sections and embodiments are not unrelated to each other unless explicitly specified otherwise, and one may represent a variation, detail, and elaboration of part or all of the other.

Further, with reference to the following embodiments, when reference is made to a number of elements (including a number of elements, numerical values, quantities, scopes, etc.), it is to be understood that the invention is not limited to the specified numbers, but may be more or less than the specified numbers, unless, for example, explicitly stated otherwise, or where the invention is obviously limited to the specific numbers on the basis of the principle behind the invention.

Still further, with reference to the following embodiments, it goes without saying that the elements (including element steps) are not necessarily essential unless, for example, explicitly specified otherwise or obviously deemed essential on the basis of the principle behind the invention.

Similarly, with reference to the following embodiments, when reference is made to the shapes of the elements, the relative position, and so forth, thereof, it is to be understood that shapes, and so forth, for example, that are effectively approximate or similar to the specified shapes, and so forth, are included unless, for example, explicitly specified otherwise or obviously deemed otherwise on the basis of the principle behind the invention. The same applies to the numerical values, scopes, and so forth.

In all figures of the drawings, constituent members having the same function are denoted by like reference numerals, and a repeated description thereof will be omitted.

### Embodiment 1

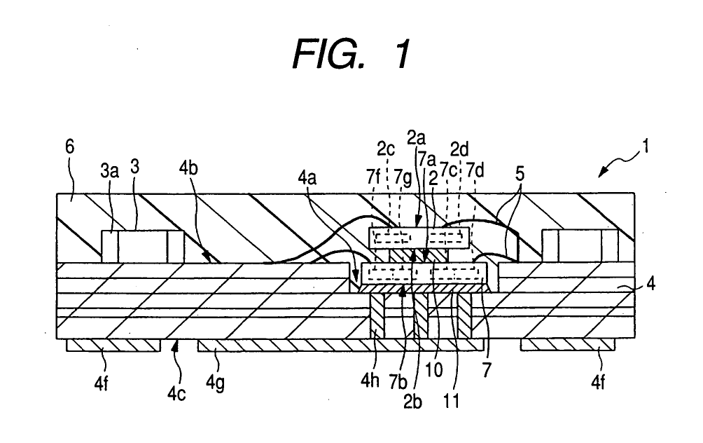

A first embodiment of the present invention will be described with reference to FIGS. 1-8 of the drawings.

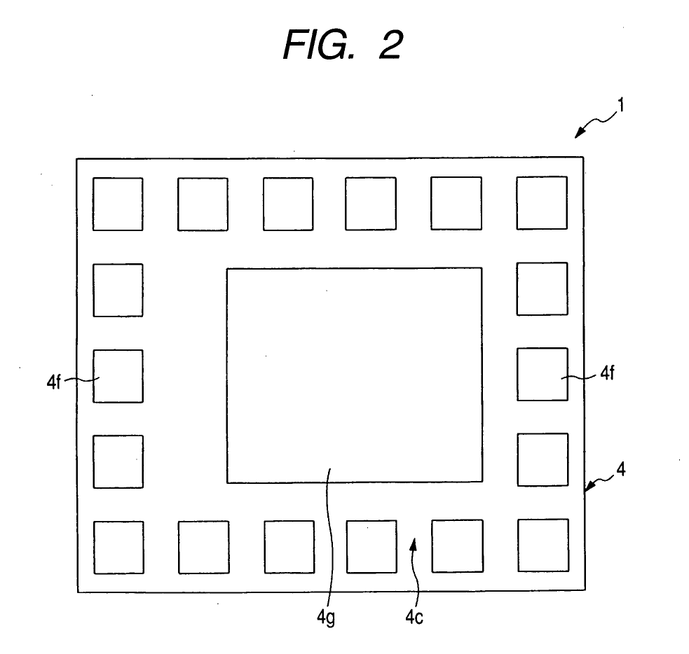

The semiconductor device according to Embodiment 1 of the invention, as shown in FIGS. 1 and 2, consists of a high frequency module designated as power amp module 1, and it has a stacked chips package structure in which a second semiconductor chip is mounted on a top surface 4b, that is, the upper surface, of a module board (printed wiring board) 4, and a first semiconductor chip is mounted over the second semiconductor chip so as to be stacked over the latter, thereby being adapted for installation primarily in small-sized portable electronic equipment, such as a cellular phone, and so forth.

The power amp module 1 shown in FIG. 1 is a high frequency amplifier of, for example, a cellular phone, for amplifying high frequencies (for example, about 900 MHz and 1800 MHz) in a plurality of stages.

The power amp module 1 according to Embodiment 1 comprises a module board 4 that is square as seen in external view, a sealing part 6 formed so as to overlie the top surface 4b of the module board 4, and a plurality of external terminals 4f, as well as an external terminal 4g for GND, provided on a backside surface 4c of the module board 4.

In assembling the power amp module 1, electronic components, including semiconductor chips, are mounted in an array over a multiple-module board, comprising a plurality of module boards 4, a resin sealing layer is subsequently formed to a predetermined height on the upper surface of the multiple-module board in such a way as to cover the electronic components and so forth, and, thereafter, the multiple-module board, including the resin sealing layer overlying the former, is cut and divided in both longitudinal and transverse directions, thereby forming a plurality of individual power amp modules. Thus, a construction is formed such that the side faces of the respective module boards 4 are flush with those of the respective sealing parts 6, and the edges of the respective sealing parts 6 are not positioned outside of the edges of the respective module boards 4.

Further, the module board 4 comprises a printed wiring board having a structure like, for example, a laminate of a plurality of dielectric layers (insulating films), including a conductor layer arranged in a predetermined wiring pattern, on the top surface 4b, and the backside surface 4c, and in inner parts thereof, respectively, while the respective conductor layers of the top surface 4b and the backside surface 4c are bonded with each other through the intermediary of vias 4h that constitute conductors extending in the direction of the thickness of the module board. With Embodiment 1, there are five dielectric layers, although the invention is not limited thereto.

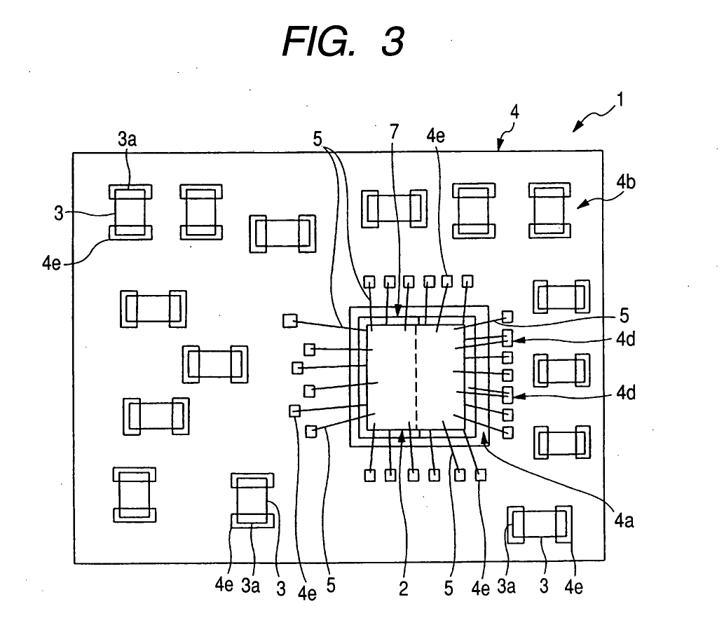

The detailed configuration of the power amp module 1 according to Embodiment 1 of the invention will be described hereinafter. The power amp module 1 comprises the module board 4, that consists of a printed wiring board having the top surface 4b and the backside surface 4c disposed opposite to the top surface 4b; a lower chip 7 that represents a second semiconductor chip mounted over the top surface 4b of the module board 4, having a first circuit operated at a first frequency and a second circuit operated at a second frequency; an upper chip 2 that represents a first semiconductor chip disposed so as to overlie over the lower chip 7, having a first circuit operated at the first frequency and a second circuit operated at the second frequency; a plurality of conductive wires 5 electrically bonding the upper chip 2 to the module board 4, and electrically bonding the lower chip 7 to the module board 4, respectively; a plurality of chip components 3, which constitute passive elements mounted around the lower chip 7 and the upper chip 2 on the module board 4, as shown in FIG. 3; and the sealing part 6 that is formed on the top surface 4b side of the module board 4 so as to cover the lower chip 7, the upper chip 2, the plurality of wires 5 and the plurality of chip components 3.

Further, with the power amp module 1, the first circuit of the upper chip 2 is disposed opposite to the second circuit of the lower chip 7, while the second circuit of the upper chip 2 is disposed opposite to the first circuit of the lower chip 7.

In this connection, as shown FIG. 1, the lower chip 7 that constitutes the second semiconductor chip is mounted, in a face-up condition, in a recessed part 4a, which consists of a cavity formed in the module board 4, and it is electrically bonded to the module board 4 through the intermediary of a solder connection 11.

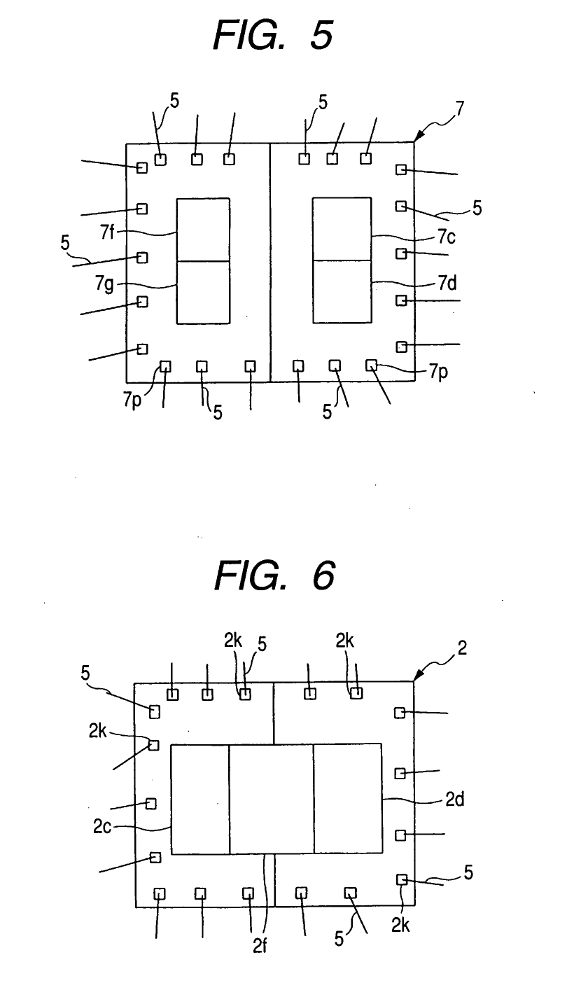

More specifically, the lower chip 7 is mounted, in the face-up condition, in the recessed part 4a so as to be recessed below the top surface 4b of the module board 4, and the backside surface 7b of the lower chip 7, on the side thereof opposite from a top surface 7a thereof, is bonded to the module board 4 with solder. Accordingly, the top surface 7a of the lower chip 7 is oriented upward, and, as shown in FIG. 3, respective pads 7p (refer to FIG. 5) of the top surface 7a are electrically bonded to terminals 4e and terminals 4d for GND of the module board 4, by a wire 5, such as a gold wire, respectively.

Further, the upper chip 2 is mounted over the top surface 7a of the lower chip 7 through the intermediary of a spacer 10, in a state as-stacked on the spacer 10, in which case the upper chip 2 is mounted in a face-up condition, with a top surface 2a thereof oriented upward as with the case of the lower chip 7. Accordingly, the backside surface 2b of the upper chip 2, on the side thereof opposite from the top surface 2a, is opposed to the top surface 7a of the lower chip 7.

The spacer 10 is formed of, for example, silicon, and so forth, but it may be formed of an insulating material other than silicon. Further, by disposing the spacer 10 between the lower chip 7 and the upper chip 2, a desired spacing can be provided between the lower chip 7 and the upper chip 2, so that it is possible to prevent the wire 5 that is bonded to the lower chip 7 from coming in contact with the upper chip 2 and the wire 5 bonded to the upper chip 2.

Further, since the upper chip 2, as well, has the top surface 2a thereof oriented upward, respective pads 2k (refer to FIG. 6) of the top surface 2a are electrically bonded to the terminals 4e and the terminals 4d for GND of the module board 4, by a wire 5, such as a gold wire, respectively.

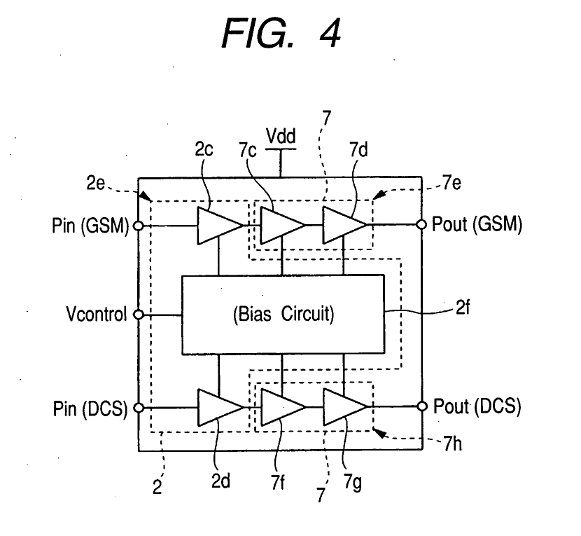

Now, the circuit block diagram of the high frequency amplifiers installed in the power amp module 1 according to Embodiment 1, as shown in FIG. 4, will be described hereinafter.

In the amplifier circuits of the high frequency amplifiers, respective input signals in two different frequency bands are amplified, respectively. Amplification is carried out in three stages in the respective amplifier circuits, and the amplifier circuits in the respective stages are controlled by a control IC (Integrated Circuit) 2f, that constitutes a bias circuit installed in the upper chip 2. With the power amp module 1 according to Embodiment 1 of the invention, the amplifier circuits in the initial stage are installed in the upper chip 2, and the amplifier circuits in a second stage and the final (a third) stage, respectively, are installed in the lower chip 7.

Now, the two different frequency bands of the power amp module 1 will be described. One of the frequency bands is for the GSM (Global System for Mobile communication) standard utilizing the first frequency, using a frequency band in a range of 880 to 915 MHz. The other is for the DCS (Digital Communication system 1800) standard utilizing the second frequency, using a frequency band in a range of 1710 to 1785 MHz. The power amp module 1 is a module adapted to both standards.

Accordingly, as shown in FIG. 4, the high frequency amplifier circuits are divided into circuit blocks 2e, 7e, and 7h, shown as surrounded by dotted lines, respectively; and, with the power amp module 1, the upper chip 2 is adapted for accommodating the circuit block 2e, while the lower chip 7 is adapted for accommodating the circuit blocks 7e and 7h.

That is, with the power amp module 1 according to Embodiment 1, the amplifier circuits in the initial stage and the control IC 2f, having relatively small power consumption and serving as the circuit block 2e, are installed in the upper chip 2, and the respective amplifier circuits in the second stage and the final (the third) stage, having large power consumption and serving as the circuit blocks 7e and 7h, respectively, are installed in the lower chip 7.

Further, the lower chip 7 is mounted in the recessed part 4a of the module board 4, in the face-up condition, so as to be electrically bonded to the module board 4 through the intermediary of the solder connection 11 underneath the backside surface 7b, and it is further bonded to the external terminal 4g for GND on the backside surface 4c of the module board 4 through a plurality of vias 4h in the module board 4 that are bonded to the solder connection 11.

Accordingly, even though the respective amplifier circuits in the second stage and the final (the third) stage, having a large power consumption, are installed in the lower chip 7, the stability of the GND connection thereof can be achieved.

Further, in such a way as to correspond to the circuit blocks 2e, 7e, and 7h, respectively, an amp 2c (the first circuit) in the initial stage, on the GSM side, and an amp 2d (the second circuit) in the initial stage, on the DCS side, are installed in the upper chip 2, while an amp 7c (the first circuit) in the second stage, on the GSM side, and an amp 7d (the first circuit) in the final stage (third stage), on the GSM side, and an amp 7f (the second circuit) in the second stage, on the DCS side, and an amp 7g (the second circuit) in the final stage (third stage), on the DCS side, are installed in the lower chip 7.

Furthermore, the control IC 2f, which is installed in the upper chip 2, controls the respective power supplies of the amp 2c in the initial stage, on the GSM side, the amp 7c in the second stage, on the GSM side, and the amp 7d in the final stage, on the GSM side, upon receiving a control signal Vcontrol, thereby controlling the respective power supplies of the amplifiers on the DCS side as well at the same time. With the power amp module 1 according to Embodiment 1, use is made of a MOSFET (Metal Oxide Semiconductor Field Effect Transistor) as an amp element; and, in this case, the upper chip 2 controls the bias applied to respective gates of the MOSFETs, thereby controlling the respective powers of the outputs thereof, that is, Pout (GSM) and Pout (DCS).

In connection with the disposition of the amplifier circuits in the upper chip 2 and the lower chip 7, respectively, for the power amp module 1 according to Embodiment 1, the first circuit in the upper chip 2 is disposed opposite to the second circuits in the lower chip 7, and the second circuit in the upper chip 2 is disposed opposite to the first circuits in the lower chip 7, as shown in FIGS. 5 and 6, in order to prevent interference by high frequencies between the wires bonded to the upper chip 2 and the lower chip 7, respectively.

More specifically, the amp 2c in the initial stage, on the GSM side, that is, the first circuit of the upper chip 2, is disposed in such a way as to oppose the amp 7f in the second stage, on the DCS side; and, the amp 7g in the final stage on the DCS side, each being a second circuit of the lower chip 7, and, further, the amp 2d in the initial stage, on the DCS side, that is, the second circuit of the upper chip 2, is disposed in such a way as to oppose the amp 7c in the second stage, on the GSM side, and the amp 7d in the final stage, on the GSM side, each being a first circuit of the lower chip 7.

That is to say, the respective amplifier circuits of the upper chip 2 and the lower chip 7, having the same frequency, are disposed on respective sides of a substantially central part of the upper chip 2 and the lower chip 7, opposite from each other, instead of on the same side of the substantially central part, thereby adopting a circuitry layout that prevents the amplifier circuits having the same frequency from being disposed in such a way as to overlap each other between the upper and lower chips.

As a result, because a wire group bonded to the first circuits of the upper chips 2 and a wire group bonded the first circuits of the lower chips 7 are not disposed in such a way as to overlap each other vertically, while a wire group bonded to the second circuits of the upper chips 2 and a wire group bonded the second circuits of the lower chips 7 are not disposed in such a way as to overlap each other vertically, the interference by high frequencies will hardly occur between the wires bonded to the upper and lower chips, respectively, at a time when the respective amps (circuits) are in operation.

More specifically, when an amp is in operation, there is a case where high frequency oscillation occurs from the wire 5 bonded to the amp, however, amps having different frequencies do not simultaneously operate, but operate at different timings, respectively, so that it is possible to prevent interference by high frequencies from easily occurring between the wires bonded to the upper and lower chips, respectively, by adopting a circuitry layout the amplifier circuits having the same frequency are not disposed in such a way as to overlap each other between the upper and lower chips, thereby implementing a stability in operation of the respective amps of the power amp module 1.

Accordingly, the reliability of the power amp module 1 can be enhanced. In addition, with the power amp module 1, by implementing the SCP structure, while achieving stability in operation of the respective amps of the upper and lower chips, respectively, a reduction in the size of the power amp module 1 can be achieved.

Further, as shown in FIG. 6, the control IC 2f is disposed substantially at the central part of the upper chips 2.

Furthermore, the plurality of chip components 3, which are passive elements mounted around the respective semiconductor chips over the top surface 4b of the module board 4 include chip resistors, chip capacitors, and so forth, and respective connection terminals 3a at both ends of the respective chip components 3 are bonded to the terminals 4e of the module board 4 with solder and so forth.

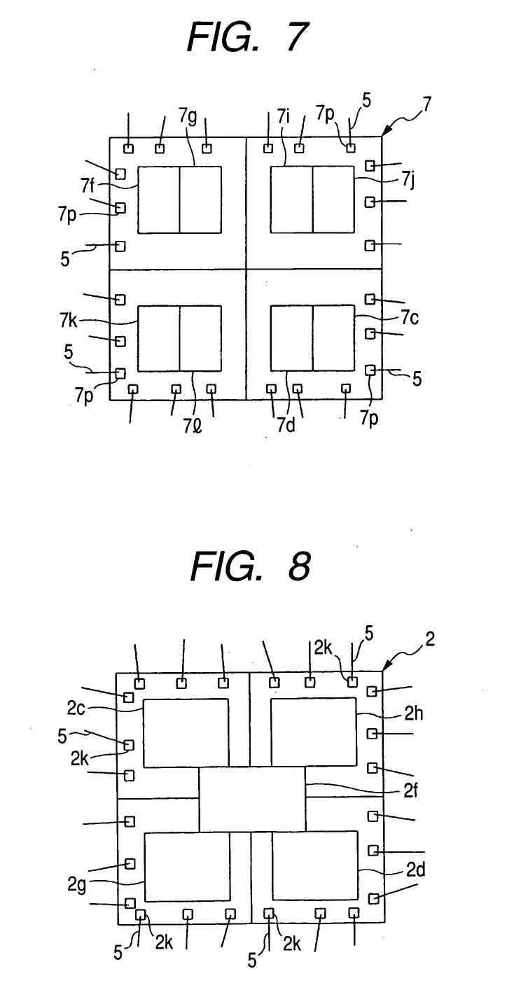

Now, a power amp module according to a variation of Embodiment 1 of the invention will be described with reference to FIGS. 7 and 8. FIGS. 7 and 8 show a layout of amplifier circuits in an upper chip 2 and a lower chip 7, respectively, in the case of the power amp module 1 being employed for four (Quad) bands.

More specifically, the upper chip 2 and the lower chip 7 each have a first circuit operated at a first frequency, a second circuit operated at a second frequency, a third circuit operated at a third frequency, and a fourth circuit operated at a fourth frequency. The layout of the respective circuits is set such that the first circuit of the upper chip 2 and the second circuit of the lower chip 7 are disposed so as to oppose each other; the second circuit of the upper chip 2 and the first circuit of the lower chip 7 are disposed so as to oppose each other; the third circuit of the upper chip 2 and the fourth circuit of the lower chip 7 are disposed so as to oppose each other; and the fourth circuit of the upper chip 2 and the third circuit of the lower chip 7 are disposed so as to oppose each other.

The power amp module according to this variation adopts, for example, the GSM standard using a frequency in a range of 880 to 915 MHz as the first frequency at which the first circuit is operated, the DCS standard using a frequency in a range of 1710 to 1785 MHz as the second frequency at which the second circuit is operated, the PCS (Personal Communications Service) standard using a frequency in a frequency band of 1.9 GHz as the third frequency at which the third circuit is operated, and the CDMA standard using a frequency in the frequency band of 1.9 GHz as the fourth frequency at which the fourth circuit is operated.

In this case, as shown in FIG. 8, a control IC 2f is disposed substantially at the central part of the upper chip 2; an amp 2c (the first circuit) in the initial stage, on the GSM side, is disposed on one side of the control IC 2f, along one chip diagonal line of the upper chip 2, while an amp 2d (the second circuit) in the initial stage, on the DCS side, is disposed on the diagonally opposite side of the amp 2c; and, similarly, an amp 2g (the third circuit) in the initial stage, on the PCS side, is disposed on one side of the control IC 2f, along the other chip diagonal line of the upper chip 2, while an amp 2h (the fourth circuit) in the initial stage, on the CDMA side, is disposed on the diagonally opposite side of the amp 2g.

Meanwhile, as shown in FIG. 7, in the lower chip 7, an amp 7c in a second stage, on the GSM side, and an amp 7d in the final stage on the GSM side, serving as the first circuits, and an amp 7f in the second stage, on the DCS side, and an amp 7g in the final stage, on the DCS side, serving as the second circuits, are disposed at positions opposite from those corresponding thereto in the case of the upper chip 2, as shown in FIG. 8, along one chip diagonal line of the lower chip 7; while, an amp 7i in a second stage, on the PCS side, and an amp 7j in the final stage, on the PCS side, serving as the third circuits, and an amp 7k in a second stage, on the CDMA side, and an amp 7l in the final stage, on the CDMA side, serving as the fourth circuits, are disposed at positions opposite from those corresponding thereto in the case of the upper chip 2, along the other chip diagonal line of the lower chip 7.

With this constitution, even with the power amp module 1 for four bands, the respective amplifier circuits of the upper chip 2 and the lower chip 7, having the same frequency, are disposed on respective sides of substantially the central part of the upper chip 2 and the lower chip 7, diagonally opposite from each other, thereby adopting a circuitry layout which prevents the amplifier circuits having the same frequency from being disposed in such a way as to overlap each other between the upper and lower chips.

Accordingly, with Embodiment 2 as well, a wire group bonded to the first circuits of the upper chips 2 and a wire group bonded to the first circuits of the lower chips 7 are not disposed in such a way as to overlap each other vertically, and the same applies to a wire group bonded to the second circuits of the upper chips 2, and a wire group bonded the second circuits of the lower chips 7, a wire group bonded to the third circuits of the upper chips 2, and a wire group bonded the third circuits of the lower chips 7. Further, the same applies to a wire group bonded to the fourth circuits of the upper chips 2 and a wire group bonded the fourth circuits of the lower chips 7, respectively, so that interference by high frequencies will hardly occur between the wires bonded to the upper chips and the lower chips, respectively, at a time when the respective amps (circuits) are in operation.

Thus, stability in operation of the respective amps of the power amp module 1 can be achieved, enabling the reliability of a power amp module to be enhanced in even in the case of a power amp module for four bands.

### Embodiment 2

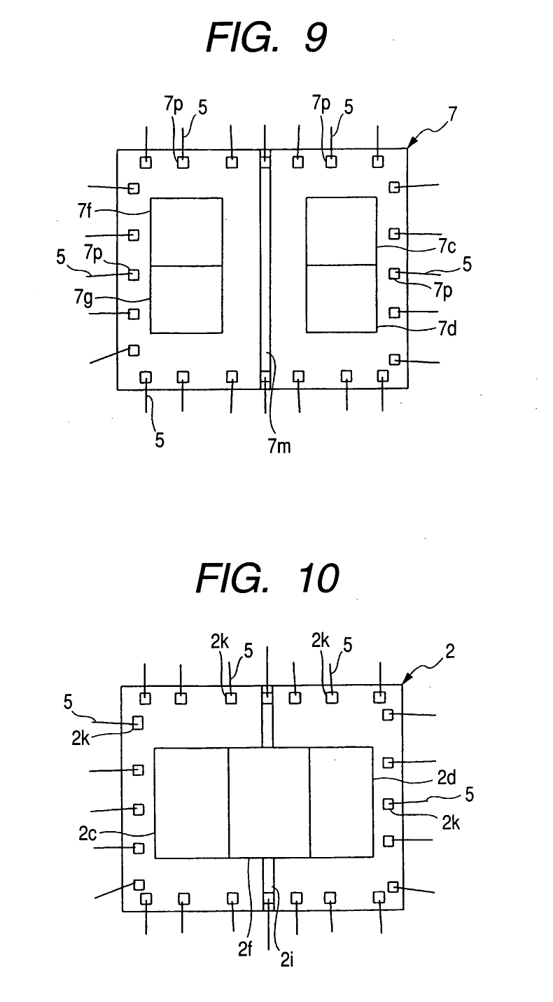

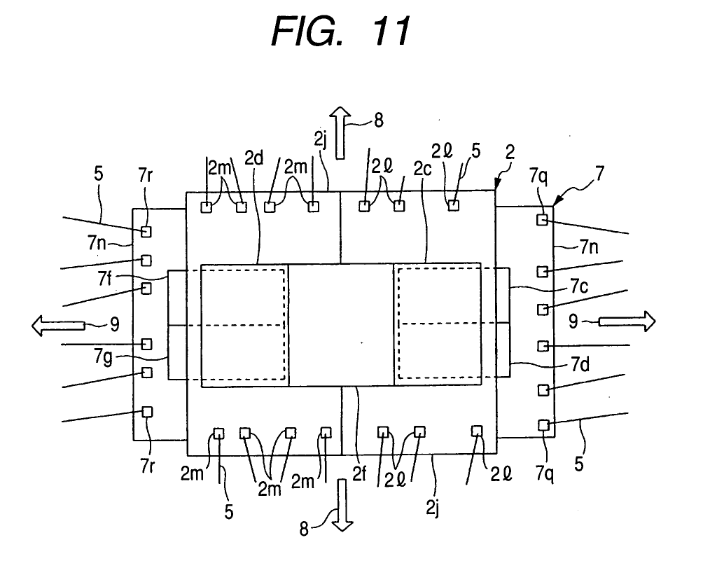

FIG. 9 is a plan view showing an example of a layout of amplifier circuits in a lower chip of Embodiment 2 of a power amp module according to the invention, and FIG. 10 is a plan view showing an example of a layout of amplifier circuits in an upper chip of Embodiment 2 of the power amp module according to the invention.

The power amp module according to Embodiment 2 has the same module construction as the power amp module 1 according to Embodiment 1, shown in FIG. 1, except that wiring layers 2i, 7m, for GND are provided between a first circuit and a second circuit in an upper chip 2 serving as a first semiconductor chip and between first circuits and second circuits in a lower chip 7 serving as a second semiconductor chip, respectively.

More specifically, as shown in FIG. 10, the wiring layer 2i for GND is formed between an amp 2c (the first circuit) in the initial stage, on a GSM side, and an amp 2d (the second circuit) in the initial stage, on a DCS side, in the upper chip 2; while, as shown in FIG. 9, the wiring layer 7m for GND is formed between an amp 7c (the first circuit) in a second stage, on the GSM side, as well as an amp 7d (the first circuit) in the final stage, on the GSM side, and an amp 7f (the second circuit) in a second stage, on the DCS side, as well as an amp 7g (the second circuit) in the final stage, on the DCS side, in the lower chip 7.

Accordingly, there is a construction where the wiring layer for GND is formed between the circuits whose frequencies differ from each other, in the respective semiconductor chips.

Thus, in the respective semiconductor chips, the electromagnetic shielding effect between high frequency amplifier circuits whose frequencies differ from each other can be enhanced, thereby enabling prevention of mutual interference of high frequencies in the respective chips. As a result, the mutual electromagnetic shielding between the high frequency amplifier circuits can be reinforced, thereby preventing the occurrence of a problem, such as oscillation outside predetermined frequency bands, and so forth. Accordingly, the reliability of the power amp module 1 according to Embodiment 2 can be enhanced.

Further, as with Embodiment 1, the amp 2c in the initial stage, on the GSM side, that is, the first circuit of the upper chip 2, is disposed in such a way as to oppose the amp 7f in the second stage, on the DCS side, and the amp 7g in the final stage on the DCS side, each being the second circuit of the lower chip 7; and, further, the amp 2d in the initial stage, on the DCS side, that is, the second circuit of the upper chip 2, is disposed in such a way as to oppose the amp 7c in a second stage, on the GSM side, and the amp 7d in the final stage, on the GSM side, each being the first circuit of the lower chip 7. Thereby, a circuitry layout is adopted in which the amplifier circuits having the same frequency are not disposed in such a way as to overlap each other between the upper and lower chips, so that interference by high frequencies can hardly occur between wires bonded to the upper and lower chips, respectively.

Thus, stability in operation of the respective amps of the power amp module is achieved, thereby enabling the reliability of the power amp module to be further enhanced.

In other respects, the power amp module according to Embodiment 2 is the same in construction as the power amp module according to Embodiment 1, therefore a duplicated description thereof will be omitted.

### Embodiment 3

FIG. 11 is a plan view showing an example of the wiring state in the upper and lower chips, respectively, of Embodiment 3 of a power amp module according to the invention.

The power amp module according to Embodiment 3 is the same in construction as the power amp module 1 according to Embodiment 1, shown in FIG. 1, except that the upper chip 2, serving as a first semiconductor chip, has a plurality of first pads 21 (first electrodes) bonded to an amp 2c in the initial stage, on the GSM side, serving as a first circuit, and a plurality of second pads 2m (second electrodes) bonded to an amp 2d in the initial stage, on the DCS side, serving as a second circuit; while, a lower chip 7, serving as a second semiconductor chip, has a plurality of first pads 7q (first electrodes) bonded to an amp 7c in a second stage, on the GSM side, and an amp 7d in the final stage, on the GSM side, each serving as the first circuit, and a plurality of second pads 7r (the second electrodes) bonded to an amp 7f in a second stage, on the DCS side, and an amp 7g in the final stage, on the DCS side, each serving as the second circuit.

Further, a plurality of wires 5 bonded to the plurality of first pads 2l as well as the plurality of second pads 2m of the upper chip 2, respectively, are disposed so as to cross a pair of sides 2j, that are opposed to each other, of a top surface 2a of the upper chip 2, extending in a direction intersecting a direction in which the first pads 7q of the lower chip 7 are arranged, respectively.

Furthermore, a plurality of wires 5 bonded to the plurality of first pads 7q as well as the plurality of second pads 7r of the lower chip 7, respectively, are disposed so as to cross a pair of sides 7n, that are opposed to each other of a top surface 7a of the lower chip 7, extending in a direction intersecting a direction in which the first pads 21 of the upper chip 2 are arranged, respectively.

In such a case, the wiring direction 8 of the plurality of wires 5 bonded to the plurality of first pads 2l as well as the plurality of second pads 2m of the upper chip 2, respectively, intersects a wiring direction 9 of the plurality of wires 5 that are bonded to the plurality of first pads 7q as well as the plurality of second pads 7r of the lower chip 7, respectively, substantially at right angles.

That is to say, with the power amp module according to Embodiment 3, in both the upper chip 2 and the lower chip 7, the electrodes are disposed along the two sides that are opposed to each other of the top surfaces 2a, 7a thereof, respectively, and in that case, the side of the upper chip 2 along which the electrodes are disposed is oriented in a direction at 90 degrees from a direction of the side of the lower chip 7 along which the electrodes are disposed. As a result, there occurs a difference by 90 degrees in orientation of the respective sides of the semiconductor chips, crossed by the respective wires 5, between the upper chip 2 and the lower chip 7, resulting in a state where the wiring direction 8 of the upper chip 2 deviates by 90 degrees from the wiring direction 9 of the lower chip 7.

As a result, the respective wires 5 bonded to the upper chip 2 and the lower chip 7 do not overlap one on top of the other, but are stretched in respective directions substantially at 90 degrees from each other, so that interference by high frequencies will hardly occur between the wires bonded to the upper and lower chips, respectively.

Thus, stability in operation of the respective amps of the power amp module is achieved, thereby enabling reliability of the power amp module to be further enhanced.

In other respects, the power amp module according to Embodiment 3 is the same in construction as the power amp module according to Embodiment 1, therefore duplicated description thereof will be omitted.

### Embodiment 4

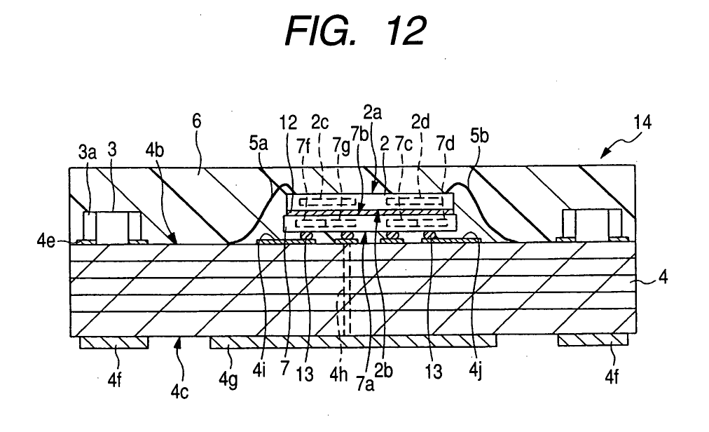

FIG. 12 is a sectional view showing the construction of a power amp module representing an example of Embodiment 4 of a semiconductor device according to the invention.

A power amp module 14 according to Embodiment 4 has a construction in which flip bonding (also called “flip chip bonding”) of a lower chip 7, that serves as a second semiconductor chip, is effected over a top surface 4b of a module board 4, and further, an upper chip 2, that serves as a first semiconductor chip, is disposed so as to overlie, in a face-up mounting state, a backside surface 7b of the lower chip 7.

Accordingly, the lower chip 7 is electrically bonded to the module board 4 through the intermediary of bump electrodes 13, while the upper chip 2 is electrically bonded to the module board 4 by wire bonding.

Further, the upper chip 2 is fixedly attached to the backside surface 7b of the lower chip 7 using, for example, an insulating adhesive 12 or the like. Furthermore, the GND of the lower chip 7 is bonded to an external terminal 4g for GND through the intermediary of the bump electrode 13 and a via 4h, while GND of the upper chip 2 is bonded to the module board 4 by wire bonding.

Further, in a power amp module 14, a first wire 5a, which is electrically bonded to an amp 2c (a first circuit) in the initial stage of the upper chip 2, on the GSM side, is disposed opposite to a first wiring 4i of the module board 4, that is electrically bonded to an amp 7f in a second stage, on the DCS side, and an amp 7g in the final stage on the DCS side, each serving as a second circuit of the lower chip 7.

Meanwhile, a second wire 5b, which is electrically bonded to an amp 2d (the second circuit) in the initial stage of the upper chip 2, on the DCS side, is disposed opposite to a second wiring 4j of the module board 4, that is electrically bonded to an amp 7c in a second stage, on the GSM side, and an amp 7d in the final stage, on the GSM side, each serving as a first circuit of the lower chip 7.

In other words, in regions of the top surface 4b of the module board 4, opposite to a wire group that is bonded to the first circuits of the upper chips 2, the second wiring 4j, which is bonded to the first circuits of the lower chips 7, respectively, is not disposed, but the first wiring 4i, which is bonded to the second circuits, is disposed; while, in regions of the top surface 4b of the module board 4, opposite to a wire group bonded to the second circuits of the upper chips 2, respectively, the first wiring 4i, which is bonded to the second circuits, is not disposed, but the second wiring 4j that is bonded to the first circuits of the lower chips 7, respectively, is disposed.

With this constitution, since amplifier circuits having the same frequency in the upper chip and the lower chip, respectively, are prevented from being disposed in such a way as to overlap between wires and board wirings, interference by high frequencies between the wires and the board wirings will hardly occur in the upper and lower chips, respectively.

Accordingly, with the power amp module 14 in which the lower chip 7 is installed by flip bonding, operation of the respective amps can be stabilized, thereby enabling the reliability of the power amp module 14 to be enhanced.

As described hereinbefore, the present invention has been specifically described with reference to various embodiments thereof, however, it is to be pointed out that the invention is not limited thereto, and it goes without saying that various changes and modifications may be made without departing from the spirit and scope of the invention.

For example, with Embodiments 1 to 4, cases have been described in which a semiconductor device is provided as a power amp module, however, the semiconductor device may consist of any module product in addition to a power amp module, provided that the semiconductor device is a module having a construction in which a plurality of semiconductor chips are stacked and mounted over a top surface 4b of a module board 4; and, in that case, the number of stages of the semiconductor chips as stacked is not limited to two stages, but may be a plurality of stages, that is, not less than two stages.

An advantageous effect obtained by a representative one of the embodiments of the invention, as disclosed in the present application, will be briefly described as follows.

That is, with a semiconductor device having a SCP structure, by disposing the first circuit of the upper chip so as to oppose the second circuits of the lower chip, and further, by disposing the second circuit of the upper chip so as to oppose the first circuits of the lower chip, interference by high frequencies will hardly occur between the wires bonded to the upper and lower chips, respectively, at a time when these circuits having respective frequencies are in operation, thereby enabling stability in circuit operation to be achieved. As a result, the reliability of the semiconductor device can be enhanced.

What is claimed is:

1. A semiconductor device comprising:
a printed wiring board having a top surface, and a backside surface, on the side of the printed wiring board, opposite from the top surface;
a second semiconductor chip mounted over the top surface of the module board, including first circuits operated by a first frequency and second circuits operated by a second frequency;
a first semiconductor chip disposed so as to overlie over the second semiconductor chip, including the first circuit and the second circuit; and
a plurality of conductive wires electrically bonding the first semiconductor chip to the printed wiring board,
wherein the first circuit of the first semiconductor chip is disposed opposite to the second circuits of the second semiconductor chip while the second circuit of the first semiconductor chip is disposed opposite to the first circuits of the second semiconductor chip.

2. A semiconductor device according to claim 1,
wherein the first semiconductor chip and the second semiconductor chip each include a third circuit operated with a third frequency, and
wherein a fourth circuit operated with a fourth frequency, and the third circuit of the first semiconductor chip is disposed opposite to the fourth circuit of the second semiconductor chip while the fourth circuit of the first semiconductor chip is disposed opposite to the third circuit of the second semiconductor chip.

3. A semiconductor device according to claim 1, further comprising:
amplifier circuits for amplifying input signals in three stages,
wherein the amplifier circuits in the initial stage of the three stages are installed in the first semiconductor chip, and the amplifier circuits in second and third stages, respectively, are installed in the second semiconductor chip.

4. A semiconductor device according to claim 1,
wherein the first and second frequencies are 880 MHz≦the first frequency≦915 MHz, and 1710 MHz≦the second frequency≦1785 MHz, respectively.

5. A semiconductor device according to claim 1,
wherein the second semiconductor chip is electrically bonded to the printed wiring board with conductive wires.

6. A semiconductor device according to claim 1,
wherein the second semiconductor chip is bonded to the printed wiring board by flip bonding.

7. A semiconductor device according to claim 6, wherein a first wire electrically bonded to the first circuit of the first semiconductor chip is disposed opposite to a first wiring of the printed wiring board, electrically bonded to the second circuits of the second semiconductor chip, respectively,
while a second wire electrically bonded to the second circuit of the first semiconductor chip is disposed opposite to a second wiring of the printed wiring board, electrically bonded to the first circuits of the second semiconductor chip, respectively.

8. A semiconductor device comprising:
a printed wiring board having a top surface, and a backside surface, on the side of the printed wiring board, opposite from the top surface;
a second semiconductor chip mounted over the top surface of the module board, including first circuits operated by a first frequency, second circuits operated by a second frequency; a plurality of first electrodes bonded to the first circuits, respectively, and a plurality of second electrodes bonded to the second circuits, respectively;
a first semiconductor chip disposed so as to overlie over the second semiconductor chip, including the first circuit, the second circuit, a plurality of first electrodes bonded to the first circuit, and a plurality of second electrodes bonded to the second circuit; and
a plurality of wires electrically bonding the first semiconductor chip and the second semiconductor chip to the printed wiring board, respectively,
wherein the plurality of wires bonded to the plurality of first electrodes and second electrodes of the first semiconductor chip, respectively, are disposed so as to cross a pair of sides, opposed to each other, of a top surface of the first semiconductor chip, extending in a direction intersecting a direction in which the first pads of the second semiconductor chip are arranged, and
wherein the plurality of wires bonded to the plurality of first electrodes and second electrodes of the second semiconductor chip, respectively, are disposed so as to cross a pair of sides, opposed to each other, of a top surface of the second semiconductor chip, extending in a direction intersecting a direction in which the first electrodes of the first semiconductor chip are arranged.

9. A semiconductor device according to claim 8,
wherein a wiring direction of the plurality of wires bonded to the plurality of first electrodes and second electrodes of the first semiconductor chip, respectively, intersects a wiring direction of the plurality of wires bonded to the plurality of first electrodes and second electrodes of the second semiconductor chip, respectively, at right angles.

10. A semiconductor device comprising:
a printed wiring board having a top surface, and a backside surface, on the side of the printed wiring board, opposite from the top surface;
a second semiconductor chip mounted over the top surface of the module board, including first circuits operated by a first frequency and second circuits operated by a second frequency;
a first semiconductor chip disposed so as to overlie over the second semiconductor chip, including the first circuit and the second circuit; and
a plurality of conductive wires electrically bonding the first semiconductor chip to the printed wiring board,
wherein a wiring layer for GND is provided between the first circuit and the second circuit of the first semiconductor chip and a wiring layer for GND is provided between the first circuits and the second circuits of the second semiconductor chip.

11. A semiconductor device according to claim 10,
wherein the first circuit of the first semiconductor chip is disposed opposite to the second circuits of the second semiconductor chip, and the second circuit of the first semiconductor chip is disposed opposite to the first circuits of the second semiconductor chip.

12. A semiconductor device comprising:
a printed wiring board having a top surface, and a backside surface, on the side of the printed wiring board, opposite from the top surface;
a second semiconductor chip mounted over the top surface of the module board, including first circuits operated by a first frequency and second circuits operated by a second frequency;
a first semiconductor chip disposed so as to overlie over the second semiconductor chip, including the first circuit and the second circuit; and
a plurality of conductive wires electrically bonding the first semiconductor chip to the printed wiring board,
wherein the wire bonded to the first circuit of the first semiconductor chip and the wires bonded to the second circuits of the second semiconductor chip, respectively, are disposed in such a way as to face each other, and the wire bonded to the second circuit of the first semiconductor chip, and the wires bonded to the first circuits of the second semiconductor chip, respectively, are disposed in such a way as to face each other.

13. A semiconductor device according to claim 12,
wherein the first circuit of the first semiconductor chip is disposed opposite to the second circuits of the second semiconductor chip, respectively, and the second circuit of the first semiconductor chip is disposed opposite to the first circuits of the second semiconductor chip, respectively.
